(19) United States
(12) Patent Application Publication
(10) Pub. No.: US 2026/0198340 A1
(43) Pub. Date: Jul. 9, 2026

(54) MEMORY HUB SYSTEM COMPRISING MEMORY HUB WITH PLURAL CHIPLET STRUCTURE AND SEMICONDUCTOR DESIGN STRUCTURE

(71) Applicant: COSIGNON, Hanam-si Gyeonggi-do (KR)

(72) Inventors: Sung Ho PARK, Incheon (KR); Hyun Jin PARK, Hanam-si Gyeonggi-do (KR)

(73) Assignee: COSIGNON, Hanam-si Gyeonggi-do (KR)

(21) Appl. No.: 19/441,941

(22) Filed: Jan. 7, 2026

(30) Foreign Application Priority Data
Jan. 7, 2025 (KR) 10-2025-0002010

(51) Int. Cl. H10W 70/60; G11C 7/10; G11C 8/12; H10B 80/00; H10D 80/30; H10W 90/00

(52) U.S. Cl. CPC H10W 70/611; G11C 7/1006; G11C 8/12; H10B 80/00; H10D 80/30; H10W 90/724

(57) ABSTRACT

According to the present disclosure, a memory hub system including a memory hub with a plurality of chiplet structures may be provided, the memory hub system comprising a processor unit including a processor; a plurality of memory hubs, each disposed to be physically separated from the processor unit and including a memory controller for controlling a connected memory; and one or more memories connected to each of the plurality of memory hubs.

### CROSS-REFERENCE TO RELATED APPLICATION

The present application claims priority to and the benefit of Korean Patent Application No. 10-2025-0002010, filed on Jan. 7, 2025, in the Korean Intellectual Property Office, the entire disclosure of which is incorporated herein by reference.

### BACKGROUND

### 1. Technical Field

The present disclosure relates to a memory hub system including a memory hub with a plurality of chiplet structures, and a semiconductor design structure. More specifically, the present disclosure relates to a semiconductor design technology for a chiplet-based memory hub using a die-to-die (D2D) technology capable of maximizing effective memory bandwidth during on-device artificial intelligence (AI) computation.

### 2. Related Art

Integrating a large number of functions into a single chip requires a large area, which physically necessitates more wiring, making it difficult to increase bandwidth. Additionally, unnecessary power consumption increases, leading to higher heat generation, which requires additional design and costs for efficient thermal management. Furthermore, since various functions are integrated, power management and optimization become complex, potentially resulting in inefficient operation.

In addition, when a semiconductor including a memory and an interface is manufactured as a single chip, manufacturing costs significantly increase if the latest process nodes are used. As the area of a single chip increases, the probability of defects occurring during the manufacturing process rises, which increases the defect rate and lowers the yield, thereby raising the unit manufacturing cost. There is also a problem that the overall manufacturing cost increases due to the greater number of process steps required to manufacture a complex single chip.

Furthermore, in memory interface semiconductors manufactured through conventional bumping processes, bumps occupy a large area. In particular, the data path extending out of the chip through physical conductors such as a PCB becomes long, limiting the bandwidth per unit area. The increase in the data transmission path causes transmission speeds to slow down, leading to a degradation in system performance.

With the recent emergence of consumer memories operating at ultra-high frequencies, there is a demand for a new chiplet-based memory hub structure and semiconductor design technology capable of high-speed data transmission between chips and realizing data transmission with high bandwidth and low latency, in order to prevent memory bottlenecks occurring in various on-device computation-intensive applications.

### SUMMARY

Embodiments of the present disclosure are directed to providing a semiconductor device including a memory hub with a chiplet structure, and a semiconductor design structure.

Furthermore, embodiments of the present disclosure are directed to providing a semiconductor device and a design technology that configure a memory hub based on a chiplet structure connecting and configuring a plurality of individual dies. This allows each chiplet to be manufactured at an optimal process node to achieve defect rate reduction and cost reduction, enables continuous performance improvement through the upgrade and replacement of individual chiplets, and reduces latency through direct chip-to-chip connection via a D2D interface.

Also, embodiments of the present disclosure are directed to providing a semiconductor device and a design technology that directly connect chips to each other through a D2D interface composed of small-sized micro bumps (uBumps) on an interposer. This occupies less space compared to a single area, enabling high-bandwidth connection between chiplets, realizing data transmission with high bandwidth and low latency, improving efficiency and performance by integrating individual chiplets on the interposer, and achieving power loss reduction and power efficiency improvement through a shorter physical distance compared to conventional structures.

In addition, embodiments of the present disclosure are directed to providing a memory interface and memory hub configuration that adopts a structure of placing micro bump (uBump)-based consumer memory on an interposer. This can increase routing density through efficient spatial arrangement, thereby shortening physical distance to reduce signal distortion and latency. It allows for flexible support of evolving ultra-high-frequency consumer memories to reduce performance improvement, upgrade, and development costs, satisfies individual requirements using consumer memories necessary for various applications, and prevents memory bottlenecks occurring in on-device computation-intensive applications by supporting high-frequency memory.

The problems to be solved by the present disclosure are not limited to those mentioned above, and other technical problems not specifically mentioned will be clearly understood by those skilled in the art from the following description.

According to an embodiment of the present disclosure, a memory hub system including a memory hub with a plurality of chiplet structures may be provided, the system comprising: a processor unit including a processor; a plurality of memory hubs, each physically separated from the processor unit and including a memory controller for controlling a connected memory; and one or more memories connected to each of the plurality of memory hubs.

Here, the processor may include at least one of a CPU, a GPU, and an NPU.

Also, the processor unit may further include a first die-to-die (D2D) interface unit for connecting with the plurality of memory hubs configured as individual dies, and each of the plurality of memory hubs may include a second die-to-die (D2D) interface unit for connecting with the processor unit configured as an individual die. The processor unit and the memory hub may be connected to transmit and receive data through the first D2D interface unit and the second D2D interface unit.

Furthermore, the first D2D interface unit and the second D2D interface unit may each include a D2D physical interface (PHY) at a lower portion and a D2D controller at an upper portion.

In addition, each of the plurality of memory hubs may include a memory physical interface (PHY) at a lower portion.

Also, the processor unit may be configured to recognize a status of memory resources connected to each of the plurality of memory hubs, and set a data path related to which memory to use for performing data transmission based on the status information of the memory resources.

Furthermore, a memory hub corresponding to a memory resource allocated by the processor unit may be configured to check memory status information regarding one or more memories connected thereto, and update a memory mapping and routing table based on the allocated memory in the memory hub corresponding to the allocated memory resource.

According to the present disclosure, through an on-device AI consumer memory hub chiplet interface technology, a main processor such as a CPU, GPU, or NPU, which performs on-device AI computations that are expected to increase, may access a high-performance consumer memory via a D2D interface, thereby providing the effect of accelerating high-speed computation.

Furthermore, according to the present disclosure, the convergence of interposer-based next-generation consumer memory interface technology and D2D technology enables the implementation of an ultra-high-speed and low-power data transmission technology for on-device AI computation data.

In addition, according to the present disclosure, it is possible to implement a memory access technology through a Die-to-Die (D2D) interface, which is essential for a chiplet configuration.

The effects of the present disclosure are not limited to those mentioned above, and other effects not specifically mentioned will be clearly understood by those skilled in the art from the following description.

### BRIEF DESCRIPTION OF THE DRAWINGS

FIG. 1 is a conceptual diagram for explaining a structure of a semiconductor device and a semiconductor package according to a conventional memory interface structure.

FIGS. 2A and 2B are a perspective view and a cross-sectional view illustrating a semiconductor device constituting a memory hub with a chiplet structure according to an embodiment of the present disclosure.

FIG. 3 is an exemplary view for explaining a configuration of a semiconductor device constituting a memory hub with a chiplet structure according to another embodiment of the present disclosure.

FIG. 4 is an exemplary view comparatively illustrating the size of a micro bump (uBump) according to an embodiment of the present disclosure.

FIG. 5 is a conceptual diagram for explaining a configuration of a memory hub system with a chiplet structure according to an embodiment of the present disclosure.

FIG. 6 is a flowchart for explaining a memory operation method in a memory hub system according to an embodiment of the present disclosure.

### DETAILED DESCRIPTION

Hereinafter, the present disclosure will be described in detail with reference to the accompanying drawings so that those skilled in the art can easily practice the present disclosure. However, the present disclosure may be embodied in various different forms and is not limited to the embodiments described herein. The terms used herein are intended to describe the embodiments and are not intended to limit the present disclosure. In this specification, a singular form also includes a plural form unless specifically stated otherwise in a phrase. As used herein, the terms “comprises” and “comprising” do not exclude the presence or addition of one or more other components, steps, operations, and/or elements to the mentioned components, steps, operations, and/or elements. In the following description, detailed descriptions of related well-known technologies that are determined to may obscure the gist of the present disclosure will be omitted. Hereinafter, embodiments according to the present disclosure will be described in detail with reference to the attached drawings. The configuration of the present disclosure and its operational effects will be clearly understood through the following detailed description.

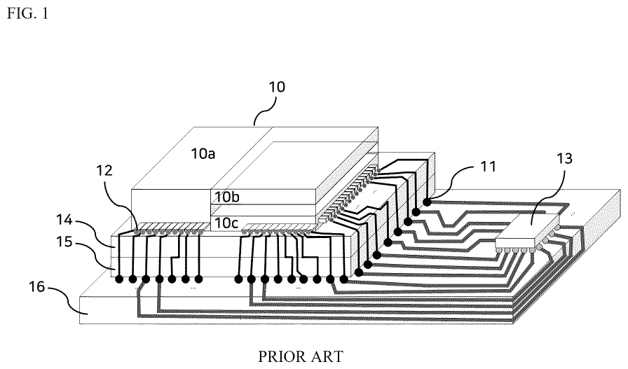

FIG. 1 is a conceptual diagram for explaining a structure of a semiconductor device and a semiconductor package according to a conventional memory interface structure.

Referring to FIG. 1, according to the conventional memory interface structure, a single chip 10 composed of one die includes a processor 10a composed of, for example, a CPU, GPU, NPU, etc., a memory controller 10b, and a memory physical interface (PHY) 10c. It may be connected to a memory 13 through wiring connections via a plurality of package bumps 11 disposed on a PCB substrate 16, passing through a lower package substrate 15 via a plurality of bumps 12 disposed on an interposer 14.

In this case, since the processor function and the memory control function are integrated into the single chip 10, it occupies a large area, physically requiring more wiring, making it difficult to increase bandwidth. Unnecessary power consumption increases, leading to higher heat generation, which requires additional design and costs for efficient thermal management. Since various functions are integrated, power management and optimization become complex, which may cause inefficient operation.

In addition, in the existing memory interface semiconductor, package bumps 11 such as solder ball bumps occupy a large area within the PCB substrate 16 connected to the memory. In particular, the data path extending out of the chip through a physical conductor such as the PCB substrate 16 becomes long, limiting bandwidth per unit area. The increase in the data transmission path slows down transmission speed, which may lead to degradation in system performance.

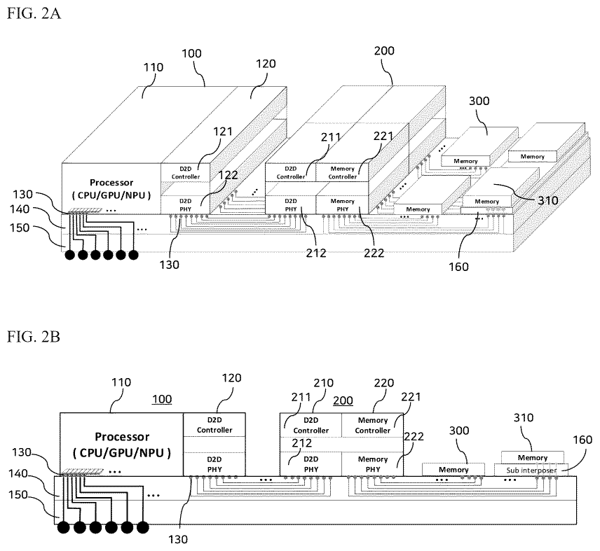

FIGS. 2A and 2B are a perspective view and a cross-sectional view illustrating a semiconductor device constituting a memory hub with a chiplet structure according to an embodiment of the present disclosure.

Referring to FIGS. 2A and 2B, a memory hub system is configured through a chiplet structure in which a processor unit 100 and a memory hub 200 are composed of individual dies and connected. By manufacturing chiplet-based individual dies at optimal process nodes, the defect rate can be reduced and manufacturing costs can be lowered. Not only is continuous performance improvement possible through the upgrade and replacement of individual chiplet structures, but latency can also be reduced through direct chip connection via a die-to-die (D2D) interface.

Referring to FIGS. 2A and 2B, the semiconductor device including a memory hub with a chiplet structure may include an interposer 140, a processor unit 100 disposed on the interposer 140, one or more memory hubs 200 disposed on the interposer 140 and physically separated from the processor unit 100, and one or more memories 300 disposed physically separated from the memory hub 200. Also, the interposer 140 may be disposed on a package substrate 150. Furthermore, the processor unit 100, the memory hub 200, and the plurality of memories 300 are not disposed in a stacked structure on the interposer 140 but are disposed in a lateral direction to each other, thereby integrating individual chips on a single interposer to improve efficiency and performance.

Here, the processor unit 100 is composed of a processor 110, which may be a CPU, GPU, NPU, etc., and a die-to-die (D2D) interface unit 120 for connection with a plurality of memory hubs 200 composed of physically separated individual dies. The memory hub 200 is also composed of a die-to-die (D2D) interface unit 210 for connecting with the processor 110 composed of an individual die, and a memory control unit 220 for controlling connected memories. The processor unit 100 and the memory hub 200 may be connected to transmit and receive data through the respective D2D interface units 120 and 210. The memory control unit 220 of the memory hub 200 may include a memory controller 221 at an upper portion and a memory physical interface (PHY) 222 at a lower portion.

In addition, the D2D interface unit 120 of the processor unit 100 may include a D2D physical interface (PHY) 122 at a lower portion and a D2D controller 121 at an upper portion. Similarly, the D2D interface unit 210 of the memory hub 200 may include a D2D physical interface (PHY) 212 at a lower portion and a D2D controller 211 at an upper portion.

Also, the D2D physical interfaces (PHY) 122 and 212 may include a plurality of micro bumps 130 disposed on the interposer 140. For example, the micro bumps 130 may have a diameter size of 30 μm to 60 μm. Furthermore, the memory 300 connected to the memory hub 200 may be packaged with a plurality of micro bumps, and such memory 300 may be connected to the memory hub 200 through the memory physical interface (PHY) 222 via the interposer 140. The processor unit 100 and the one or more memory hubs 200 may be connected through wiring disposed within the interposer 140 via the micro bumps 130. Also, the one or more memory hubs 200 and the one or more memories 300 may be connected through wiring disposed within the interposer 140 via the micro bumps 130.

In this way, by directly connecting the processor unit 100 and the memory hub 200 composed of individual dies through the D2D interface composed of micro bumps on the interposer 140, less space is occupied compared to a single area, enabling data transmission with high bandwidth and low latency between chips. It improves efficiency and performance while integrating individual chips through the interposer and reduces power loss through a shorter physical distance compared to conventional substrate structures, thereby increasing power efficiency. In addition, by adopting a structure in which micro bump-based consumer memories are placed on the interposer, routing density can be increased through efficient spatial arrangement, thereby reducing physical distance and reducing signal distortion and latency. It allows for flexible support of evolving ultra-high-frequency consumer memories to reduce performance upgrade costs and satisfy the requirements of various applications. Here, the consumer memory refers to each individual memory in a memory where a plurality of memory chipsets are used in a module form.

Meanwhile, in the case of a memory 310 packaged with general bumps instead of micro bump size, a sub-interposer 160 may be additionally disposed between the interposer 140 and the memory 310, and a plurality of micro bumps may be disposed under the sub-interposer 160 to support memories of various bump standards.

Also, the memories 300 and 310 herein may be composed of various types of memory, and may include, for example, Double Data Rate Synchronous Dynamic Random Access Memory (DDR SDRAM), Low Power Double Data Rate (LPDDR) SDRAM, Graphics Double Data Rate (GDDR) SDRAM, Rambus Dynamic Random Access Memory (RDRAM), etc. They may also be implemented in various forms such as Static DRAM (SDRAM), High Bandwidth Memory (HBM), or Processor-In-Memory (PIM), but are not limited thereto.

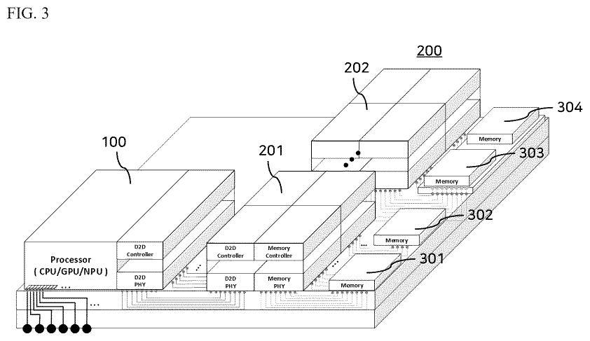

FIG. 3 is an exemplary view for explaining a configuration of a semiconductor device constituting a memory hub with a chiplet structure according to another embodiment of the present disclosure.

Referring to FIG. 3, one processor unit 100 may be connected to a plurality of memory hubs 201 and 202, and a plurality of memories 301, 302, 310, etc., may be connected to each of the plurality of memory hubs 201 and 202. As such, according to the memory hub system structure according to the present disclosure, a design structure capable of more freely expanding a plurality of memory hubs and memories using a D2D interface through flexible scalability can be provided.

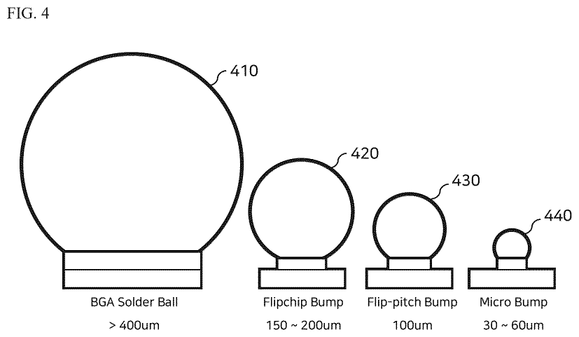

FIG. 4 is an exemplary view comparatively illustrating the size of a micro bump (uBump) according to an embodiment of the present disclosure.

Referring to FIG. 4, the size of the micro bump 130 used in the present disclosure has a diameter size of 30 μm to 60 μm. The size of a solder ball used in a conventional Ball Grid Array (BGA) type memory has a size of 400 μm or more, a standard flip-chip bump used in a flip-chip has a size of 150 to 200 μm, and a flip-pitch bump has a size of 100 μm.

As such, in the present disclosure, by connecting consumer memory composed of micro bumps (uBumps) through an interposer, routing to more memories is possible compared to a single area of existing ball-type memory. Therefore, it is possible to configure n times or more memory interface channels. Since high routing density can be configured compared to configuring an interface with ball-type consumer memory in a single area, the physical distance between the consumer memory and the physical interface (PHY) can be reduced, making it advantageous for matching timing and skew compared to conventional methods. Also, chipsets connected with micro bumps have the advantage of being able to configure a power mesh more precisely, enabling stable signal output.

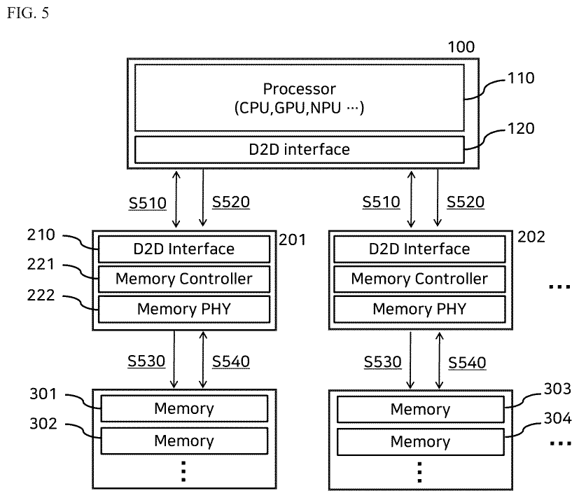

FIG. 5 is a conceptual diagram for explaining a configuration of a memory hub system with a chiplet structure according to an embodiment of the present disclosure.

Referring to FIG. 5, the D2D interface-based memory hub system according to an embodiment of the present disclosure may be composed of a processor unit 100, a plurality of memory hubs 201 and 202, and a plurality of memories 301, 302, 303, and 304. First, the processor unit 100 includes a processor 110, which may be composed of a CPU, GPU, NPU, etc., and a D2D interface unit 120 for a D2D interface. Each memory hub 201 may include a D2D interface unit 210 for a D2D interface, a memory controller 221, and a memory physical interface (PHY) 222.

First, the processor unit 100 may detect and recognize the plurality of memory hubs 201 and 202 to recognize the status of memory resources connected to each memory hub, for example, whether memory allocation is available (S510). The processor unit 100 may set a data path based on the status information of the memory resources recognized through each memory hub 201 and 202 (S520). For example, based on the status information of the memory resources of the first memory hub 201 and the second memory hub 202, it may be determined which memory hub among the first memory hub 201 or the second memory hub 202 will be used to perform data transmission.

By allocating memory using a plurality of memories connected to each memory hub using the determined memory hub, data can be dynamically distributed (S530). At this time, it may be determined which memory to use to perform data transmission based on the resource status information of each of the plurality of memories connected to each memory hub. Data transmission may be performed using the determined memory (S540).

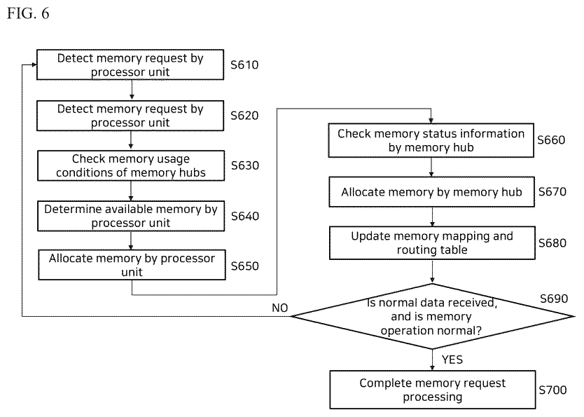

FIG. 6 is a flowchart for explaining a memory operation method in a memory hub system according to an embodiment of the present disclosure.

Referring to FIG. 6, first, the processor unit 100, which is the main chipset, may detect a memory resource request (S610).

Next, the processor unit 100 may analyze the memory request (S620) and check the memory usage status of the plurality of memory hubs 200 (S630).

The processor unit 100 may determine an available memory (S640) and allocate the corresponding memory resource in the processor unit 100 (S650).

The memory hub corresponding to the corresponding memory resource may check memory status information regarding one or more memories connected to itself (S660) and allocate memory in the memory hub (S670).

Based on the allocated memory, the memory mapping and routing table may be updated (S680). It is determined whether data reception is normal and memory operation is normal (S690), and if the operation is normal, the memory request processing may be completed (S700).

The embodiments disclosed in the specification of the present disclosure are merely examples, and the present disclosure is not limited thereto. The scope of the present disclosure should be interpreted by the claims below, and all technologies within the equivalent range should be interpreted as being included in the scope of the present disclosure.

What is claimed is:

1. A memory hub system including a memory hub with a plurality of chiplet structures, the memory hub system comprising:
a processor unit including a processor;
a plurality of memory hubs, each disposed to be physically separated from the processor unit and including a memory controller for controlling a connected memory; and
one or more memories connected to each of the plurality of memory hubs,
wherein the processor includes at least one of a CPU, a GPU, and an NPU,
wherein the processor unit further includes a first die-to-die (D2D) interface unit for connecting with the plurality of memory hubs configured as individual dies, each of the plurality of memory hubs includes a second die-to-die (D2D) interface unit for connecting with the processor unit configured as an individual die, and the processor unit and the memory hub are connected to transmit and receive data through the first D2D interface unit and the second D2D interface unit,
wherein the first D2D interface unit and the second D2D interface unit each include a D2D physical interface (PHY) at a lower portion and a D2D controller at an upper portion, and
wherein each of the plurality of memory hubs includes a memory physical interface (PHY) at a lower portion.

2. The memory hub system of claim 1, wherein the processor unit is configured to recognize a status of memory resources connected to each of the plurality of memory hubs, and set a data path related to which memory to use for performing data transmission based on status information of the memory resources.

3. The memory hub system of claim 2, wherein a memory hub corresponding to a memory resource allocated by the processor unit is configured to check memory status information regarding one or more memories connected thereto, and update a memory mapping and routing table based on the allocated memory in the memory hub corresponding to the allocated memory resource.
